(19) United States
(12) Patent Application Publication
(10) Pub. No.: US 2024/0346216 A1
(43) Pub. Date: Oct. 17, 2024

(54) AUXILIARY COLORING METHOD FOR APERIODIC PATTERN QUAD-COLOR SPLIT

(71) Applicant: Shanghai Huali Integrated Circuit Corporation, Shanghai (CN)

(72) Inventor: Baoxuan LI, Shanghai (CN)

(73) Assignee: Shanghai Huali Integrated Circuit Corporation, Shanghai (CN)

(21) Appl. No.: 18/426,033

(22) Filed: Jan. 29, 2024

(30) Foreign Application Priority Data
Apr. 13, 2023 (CN) 202310392881.5

(51) Int. Cl. G06F 30/30

(52) U.S. Cl. CPC G06F 30/30

(57) ABSTRACT

The present application provides an auxiliary coloring method for an aperiodic pattern quad-color split, including: analyzing a split rule and a pattern design rule according to a lithography capability; finding a general solution of the split rule that satisfies the lithography capability, wherein the general solution covers a pattern distribution allowed by the pattern design rule; extracting a partial rule from the general solution, and pre-coloring patterns; and writing a script to split remaining uncolored patterns using software. According to the present application, by analyzing the rules, the amount of computer computation can be reduced greatly, thereby limiting the problem within the reach of the computer computation capability and obtaining a correct split solution within short running time.

### CROSS-REFERENCES TO RELATED APPLICATIONS

This application claims priority to Chinese patent application No. CN 202310392881.5, filed on Apr. 13, 2023 at CNIPA, and entitled “AUXILIARY COLORING METHOD FOR APERIODIC PATTERN QUAD-COLOR SPLIT”, the disclosure of which is incorporated herein by reference in entirety.

### TECHNICAL FIELD

The disclosure relates to the technical field of semiconductors, in particular to an auxiliary coloring method for an aperiodic pattern quad-color split.

### BACKGROUND

Some critical layers of low nodes are beyond the lithography limit of a 193 nm light source due to extremely small sizes, and therefore a pattern split into a plurality of masks is required and realized via multiple times of exposure-etching.

A pattern split generally can be scripted to provide a rule and then implemented by dedicated software. However, in a split into more than two masks, such as a quad-color pattern (QP) split, particularly for aperiodic patterns of a complex environment, since there is no algorithm for obtaining an exact solution in polynomial time, a coloring failure may occur due to a computational overload (even if the pattern is splittable, the computer cannot find a correct coloring solution, and would continue the computation for several days and then output a conflict solution, which is considered thereby as an optimal solution).

### BRIEF SUMMARY

In view of the above defects in the prior art, the objective of the present application is to provide an auxiliary coloring method for an aperiodic pattern quad-color split, so as to solve the problem in the prior art that, for an aperiodic pattern of a complex environment, since there is no algorithm for obtaining an exact solution in polynomial time, a coloring failure may occur due to a computational overload.

In order to achieve the above objective and other related objectives, the present application provides an auxiliary coloring method for an aperiodic pattern quad-color split, at least including:
step 1. analyzing a split rule and a pattern design rule according to a lithography capability;
step 2. finding a general solution of the split rule that satisfies the lithography capability, wherein the general solution covers a pattern distribution allowed by the pattern design rule;
step 3. extracting a partial rule from the general solution, and pre-coloring patterns; and
step 4. writing a script to split remaining uncolored patterns using software.

In an example, the pattern design rule in step 1 cannot implement all the patterns by means of translation of a specific unit, and requires a split into four masks.

In an example, the partial rule in the general solution in step 3 is that some regularly distributed patterns belong to the same mask.

In an example, pre-coloring of the patterns in step 3 is followed by optimization of the pre-coloring so that split results are distributed more evenly.

In an example, the lithography capability in step 1 is resolving power of a light source.

In an example, the split rule in step 1 includes a vertical split spacing of at least 50 nm and a horizontal split spacing of at least 90 nm.

As stated above, the auxiliary coloring method for an aperiodic pattern quad-color split of the present application has the following beneficial effects: according to the present application, by analyzing the rules, a generalized split solution is found in advance, the patterns are pre-colored manually according to the general solution, and then the remaining uncolored patterns are split using a computer, so that the amount of computer computation can be reduced greatly, thereby limiting the problem within the reach of the computer computation capability and obtaining a correct split solution within short running time.

### BRIEF DESCRIPTION OF THE DRAWINGS

FIG. 1 illustrate a schematic diagram of split seeds formed after a split according to the present application;

FIG. 2 illustrates a schematic diagram of a general solution mode for coloring according to the present application;

FIG. 3 illustrates a schematic diagram of a coloring mode taking into account split evenness according to the present application; and

FIG. 4 illustrates a schematic diagram of results of coloring B1B2 by a computer after pre-coloring of A1 and A2 according to the present application.

### DETAILED DESCRIPTION OF THE DISCLOSURE

The implementations of the present application are described below using specific embodiments, and those skilled in the art could readily understand other advantages and effects of the present application from the contents disclosed in the description. The present application can also be implemented or applied using other different specific implementations, and various details in the description can also be modified or changed based on different viewpoints and applications, without departing from the spirit of the present application.

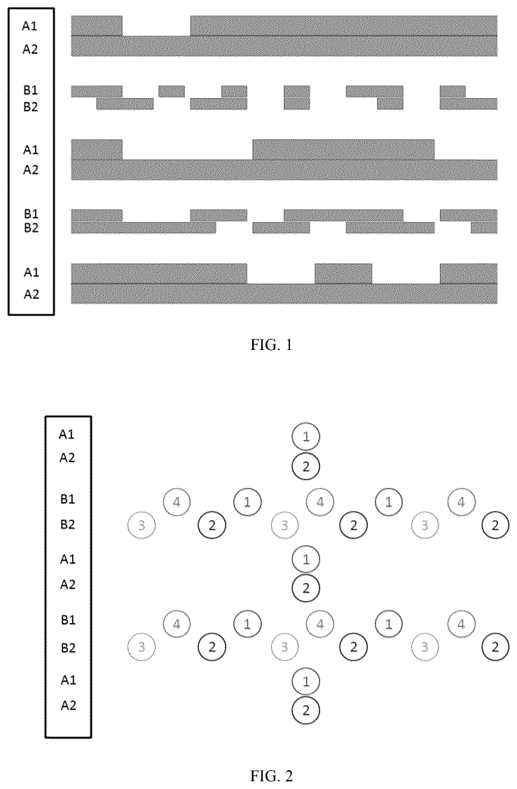

Please refer to FIG. 1 to FIG. 4. It should be noted that the drawings provided in the embodiments are only used to illustrate the basic concept of the present application in a schematic way, so the drawings only show the components related to the present application rather than being drawn according to the numbers, shapes, and sizes of the components in actual implementations. The types, numbers, and proportions of various components in actual implementations can be changed randomly, and the layout of the components may be more complicated.

The present application provides an auxiliary coloring method for an aperiodic pattern quad-color split, at least including:
Step 1. Analyze a split rule and a pattern design rule according to a lithography capability.
Step 2. Find a general solution of the split rule that satisfies the lithography capability, wherein the general solution covers a pattern distribution allowed by the pattern design rule.
Step 3. Extract a partial rule from the general solution, and pre-coloring patterns.
Step 4. Write a script to split remaining uncolored patterns using software.

In this embodiment, the pattern design rule in step 1 cannot implement all the patterns by means of translation of a specific unit, and requires a split into four masks.

In this embodiment, the lithography capability in step 1 is resolving power of a light source. In this embodiment, the split rule in step 1 includes a vertical split spacing of at least 50 nm and a horizontal split spacing of at least 90 nm. In this embodiment, the partial rule in the general solution in step 3 is that some regularly distributed patterns belong to the same mask. In this embodiment, pre-coloring of the patterns in step 3 is followed by optimization of the pre-coloring so that split results are distributed more evenly.

The present application is illustrated using a low-node MOC layer as an embodiment, and requires a split into four masks, wherein a logical region is characterized by complex, aperiodic, and asymmetrical patterns, and a computation amount of the quad-color split is far greater than the computation capability acceptable by the computer. Therefore, a pre-coloring strategy is adopted herein:

In step 1, the split rule and the pattern design rule are analyze according to the lithography capability. Depending on the resolving power of the light source, the vertical split spacing is at least 50 nm and the horizontal split spacing of at least 90 nm. Split seeds are formed after cutting of logical region patterns of a particular type. Referring to FIG. 1, FIG. 1 illustrate a schematic diagram of the split seeds formed after the split according to the present application, which are classified into four types of regions A1, A2, B1, and B2, arranged as A1, A2, B1, B2 periodically along the vertical direction, wherein patterns in every two rows spaced apart by one row can be colored with the same color (with a distance greater than 50 nm); the regions A1 and A2 have pattern spacing greater than 90 nm according to the design rule, and all the internal patterns can be colored with the same color.

In step 2, the general solution of the split rule that satisfies the lithography capability is found, wherein the general solution covers the pattern distribution allowed by the pattern design rule. As such, the general solution for coloring as shown in FIG. 2 can be obtained. FIG. 2 illustrates a schematic diagram of a general solution mode for coloring according to the present application, that is, coloring of A1, A2, A1, A2 . . . in the vertical direction is performed according to R1, R2, R1, R2 . . . , coloring in the horizontal direction inside B1 is performed according to R4, R1, R4, R1 . . . , and coloring in the horizontal direction inside B2 is performed according to R3, R2, R3, R2 . . . , in which case a solution necessarily exists.

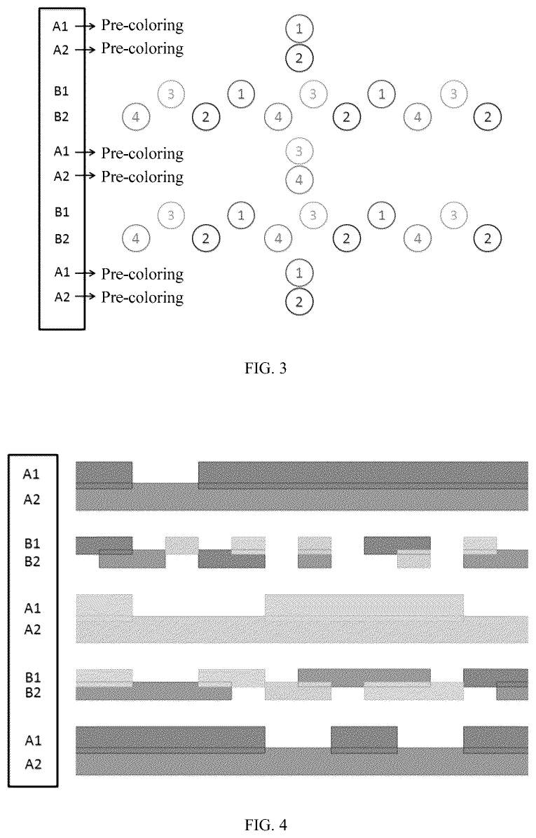

In step 3, the partial rule is extracted from the general solution, and the patterns are pre-colored. Referring to FIG. 3, FIG. 3 illustrates a schematic diagram of a coloring mode taking into account split evenness according to the present application. According to the above general solution, A1 and A2 are selected for pre-coloring. Considering the evenness of the four masks after the split, pre-coloring of A1, A2, A1, A2 . . . is changed to R1, R2, R3, R4 . . . , so that a solution apparently still can be found inside B1B2.

In step 4, the script is written to split the remaining uncolored patterns using the software. The script is written to split patterns inside B1 and B2 using the software. Results are shown in FIG. 4, and FIG. 4 illustrates a schematic diagram of the results of coloring B1 and B2 by the computer after the pre-coloring of A1 and A2 according to the present application.

Using the conventional split method, i.e., telling a basic split rule to the software so that the computer undertakes all split tasks, a 600-core computer runs 53 h to split an entire layout, outputting split results still having conflicts. Using the pre-coloring split strategy of the present application, a 600-core computer runs 24 min to finish the split of the entire layout, with correct split results.

The method provided by the present application can make it possible to publish quad-color split layers such as a low-node metal cut layer (MOC). Split problems beyond the computer computation capability can be solved by means of the method of the present application.

To sum up, according to the present application, by analyzing the rules, a generalized split solution is found in advance, the patterns are pre-colored manually according to the general solution, and then the remaining uncolored patterns are split using a computer, so that the amount of computer computation can be reduced greatly, thereby limiting the problem within the reach of the computer computation capability and obtaining a correct split solution within short running time. Therefore, the present application effectively overcomes various defects in the prior art and thus has high industrial utilization.

The above embodiments merely illustrate the principle and effect of the present application, rather than for limiting the present application. Any person skilled in the art can modify or change the above embodiments without departing from the spirit and scope of the present application. Therefore, all equivalent modifications or changes made by those with ordinary knowledge in the art without departing from the spirit and technical idea disclosed in the present application shall still be covered by the claims of the present application.

What is claimed is:

1. An auxiliary coloring method for an aperiodic pattern quad-color split, at least comprising:
step 1. analyzing a split rule and a pattern design rule according to a lithography capability;
step 2. finding a general solution of the split rule that satisfies the lithography capability, wherein the general solution covers a pattern distribution allowed by the pattern design rule;
step 3. extracting a partial rule from the general solution, and pre-coloring patterns; and
step 4. writing a script to split remaining uncolored patterns using software.

2. The auxiliary coloring method for an aperiodic pattern quad-color split according to claim 1, wherein the pattern design rule in step 1 cannot implement all the patterns by means of translation of a specific unit, and requires a split into four masks.

3. The auxiliary coloring method for an aperiodic pattern quad-color split according to claim 1, wherein the partial rule in the general solution in step 3 is that some regularly distributed patterns belong to the same mask.

4. The auxiliary coloring method for an aperiodic pattern quad-color split according to claim 1, wherein pre-coloring of the patterns in step 3 is followed by optimization of the pre-coloring so that split results are distributed more evenly.

5. The auxiliary coloring method for an aperiodic pattern quad-color split according to claim 1, wherein the lithography capability in step 1 is resolving power of a light source.

6. The auxiliary coloring method for an aperiodic pattern quad-color split according to claim 1, wherein the split rule in step 1 comprises a vertical split spacing of at least 50 nm and a horizontal split spacing of at least 90 nm.
